(19) United States
(12) Patent Application Publication
(10) Pub. No.: US 2012/0248431 A1
(43) Pub. Date: Oct. 4, 2012

(54) TRANSISTOR ARRAY SUBSTRATE

(76) Inventors: Ya-Huei HUANG, Tainan County (TW); Kuan-Yu Chen, Taoyuan County (TW); Ying-Hui Chen, Taoyuan County (TW); Te-Yu Chen, Kaohsiung City (TW)

(21) Appl. No.: 13/183,838

(22) Filed: Jul. 15, 2011

(30) Foreign Application Priority Data
Apr. 1, 2011 (TW) 100111522

(51) Int. Cl. H01L 29/786

(52) U.S. Cl. 257/43; 257/E29.273

(57) ABSTRACT

A transistor array substrate includes a substrate, a plurality of scan lines, a plurality of data lines and a plurality of pixel units. The scan lines and the data lines are all disposed on the substrate. Each pixel unit includes a transistor and a pixel electrode. The transistor is electrically connected to the pixel electrodes, the scan lines and the data lines. Each transistor includes a gate, a drain, a source, a metal-oxide-semiconductor layer and a channel protective layer. A channel gap exists between the drain and the source. The metal-oxide-semiconductor layer has a pair of side edges opposite to each other and the side edges are located at two ends of the channel gap. The channel protective layer covers the metal-oxide-semiconductor layer in the channel gap and protrudes from the side edges of the metal-oxide-semiconductor layer.

### CROSS-REFERENCE TO RELATED APPLICATION

This application claims the benefit of Taiwan Patent Application No. 100111522, filed on Apr. 1, 2011, which is hereby incorporated by reference for all purposes as if fully set forth herein.

### BACKGROUND OF THE INVENTION

1. Field of Invention

The present invention relates to a display element, and more particularly to a transistor array substrate.

2. Related Art

Currently, a liquid crystal display (LCD) having a metal-oxide-semiconductor is present. A semiconductor layer of the thin-film transistor included in the LCD is made of the metal-oxide-semiconductor. However, in general processes of the LCD, the metal-oxide-semiconductor is easy to be influenced by the gas (such as hydrogen) used for the manufacturing process, and thus the metal-oxide-semiconductor becomes a conductor. Therefore, the thin-film transistor may lose a switching function, so that the LCD fails to display images normally.

### SUMMARY OF THE INVENTION

The present invention is directed to a transistor array substrate capable of protecting a metal-oxide-semiconductor from being influenced by the gas used for the manufacturing process.

The present invention provides a transistor array substrate including a substrate, a plurality of scan lines, a plurality of data lines, a plurality of pixel units, and a plurality of first protective pads. The scan lines and the data lines are all disposed on the substrate and crossing each other. The pixel units each include a transistor and a pixel electrode. Each of the transistors includes a gate, a drain, a source, a metal-oxide-semiconductor layer, and a channel protective layer. The gate is disposed on the substrate and electrically connected to one of the scan lines. The drain is electrically connected to one of the pixel electrodes. The source is electrically connected to one of the data lines. A channel gap exists between the drain and the source. The metal-oxide-semiconductor layer is disposed between the gate and the drain, and between the gate and the source. The metal-oxide-semiconductor layer has a pair of side edges, and the side edges are located opposite to each other and are located at two ends of the channel gap. The channel protective layer covers the metal-oxide-semiconductor layer in the channel gap and protrudes from the side edges of the metal-oxide-semiconductor layer. The first protective pads are disposed between the scan lines and the data lines, and located at a plurality of intersections of the scan lines and the data lines respectively. Each of the first protective pads includes a first pad layer and a second pad layer, and the first pad layers are located between the second pad layers and the scan lines.

Based on the foregoing, the channel protective layer covers the metal-oxide-semiconductor layer in the channel gap and protrudes from two side edges of the metal-oxide-semiconductor layer, thereby separating the drain from the source. Therefore, the channel protective layer can isolate the metal-oxide-semiconductor layer in the channel gap from the gas used for the manufacturing process, so as to further protect the metal-oxide-semiconductor from being influenced by the gas used for the manufacturing process.

In order to make the aforementioned features and advantages of the present invention comprehensible, preferred embodiments accompanied with figures are described in detail below.

### BRIEF DESCRIPTION OF THE DRAWINGS

The present invention will become more fully understood from the detailed description given herein below for illustration only, and thus are not limitative of the present invention, and wherein:

FIG. 1A is a schematic top view of a transistor array substrate according to a first embodiment of the present invention;

FIG. 1B is a schematic cross-sectional view taken along line I-I in FIG. 1A;

FIG. 1C is a schematic cross-sectional view taken along line J-J in FIG. 1A;

FIG. 2A is a schematic top view of a transistor array substrate according to a second embodiment of the present invention;

FIG. 2B is a schematic cross-sectional view taken along line K-K in FIG. 2A; and

FIG. 2C is a schematic cross-sectional view taken along line L-L in FIG. 2A.

### DETAILED DESCRIPTION OF THE INVENTION

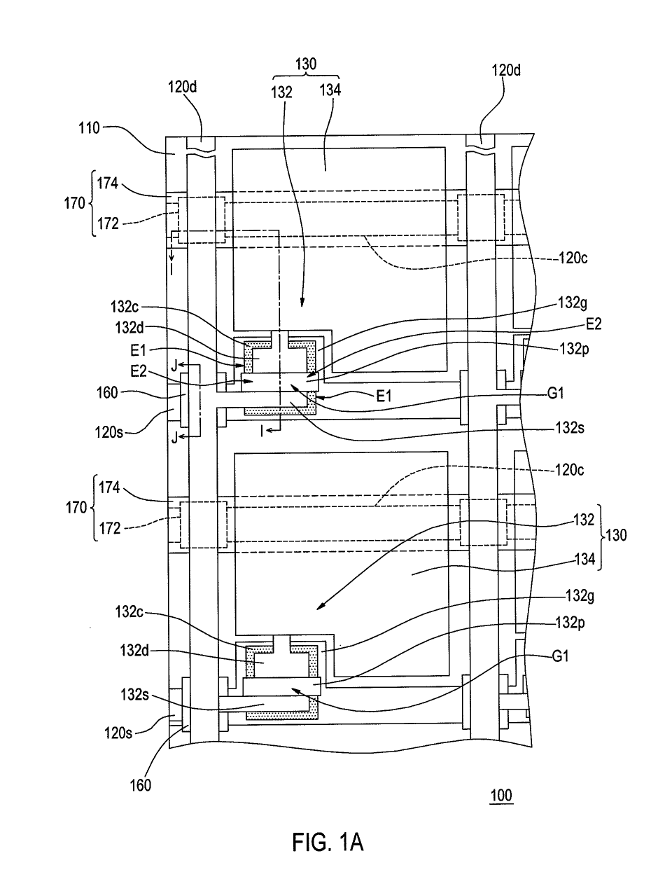

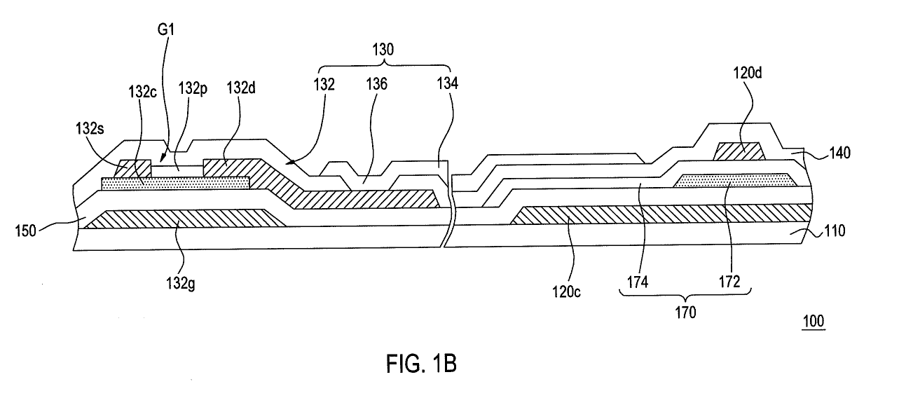

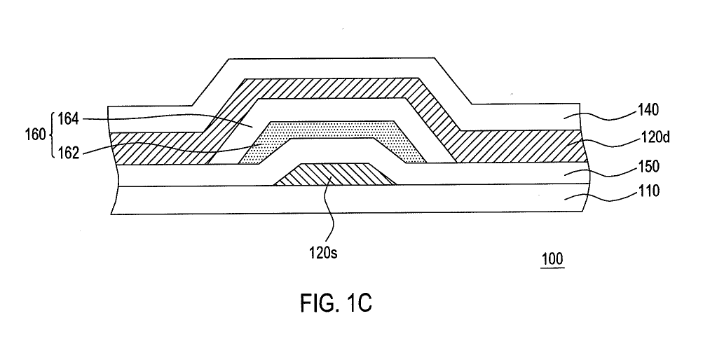

FIG. 1A is a schematic top view of a transistor array substrate according to a first embodiment of the present invention, and FIG. 1B is a schematic cross-sectional view taken along line I-I in FIG. 1A. Referring to FIG. 1A and FIG. 1B, the transistor array substrate 100 of the first embodiment includes a substrate 110, a plurality of scan lines 120s, a plurality of data lines 120d and a plurality of pixel units 130. The scan lines 120s, the data lines 120d and the pixel units 130 are all disposed on the substrate 110.

The scan lines 120s cross the data lines 120d. The scan lines 120s are arranged side by side, and the data lines 120d are arranged side by side, so that the scan lines 120s and the data lines 120d are arranged in a grid. That is, the scan lines 120s and the data lines 120d form a grid structure as shown in FIG. 1A. Moreover, in this embodiment, all of the data lines 120d may be located above the scan lines 120s.

Each pixel unit 130 includes a transistor 132 and a pixel electrode 134. Each transistor 132 is electrically connected to one pixel electrode 134, one scan line 120s and one data line 120d. In detail, all of the transistors 132 may be field-effect transistors (FETs), so each transistor 132 includes a gate 132g, a drain 132d, a source 132s and a metal-oxide-semiconductor layer 132c. Moreover, a material of the metal-oxide-semiconductor layer 132c may be an In—Ga—Zn—O (IGZO) semiconductor or an In—Sn—Zn—O (ITZO) semiconductor.

In each transistor 132, the metal-oxide-semiconductor layer 132c is disposed between the gate 132g and the drain 132d, and between the gate 132g and the source 132s, as shown in FIG. 1B. Therefore, the source 132s and the drain 132d partially cover the metal-oxide-semiconductor layer 132c. In addition, each metal-oxide-semiconductor layer 132c has a pair of side edges E1. The side edges E1 are located opposite to each other and are located at two ends E2 of the channel gap G1.

Each gate 132g is disposed on the substrate 110 and is electrically connected to one of the scan lines 120s. Each drain 132d is electrically connected to one of the pixel electrodes 134, and each source 132s is electrically connected to one of the data lines 120d. A channel gap G1 exists between the drain 132d and the source 132s, so the drains 132d are not directly connected to the sources 132s.

Each pixel unit 130 may further include a conductive column 136, and the drains 132d may be electrically connected to the pixel electrodes 134 via the conductive columns 136. The conductive columns 136 separately are connected between the pixel electrodes 134 and the drains 132d. The transistor array substrate 100 may further include an insulating layer 140 (as shown in FIG. 1B). The insulating layer 140 may be located between the transistors 132 and the pixel electrodes 134 and cover the transistors 132. The conductive columns 136 are all disposed in the insulating layer 140.

Accordingly, a material of the insulating layer 140 may be silicon oxide, for example, silica (silicon dioxide, SiO₂), and the insulating layer 140 may be formed by chemical vapor deposition (CVD). Here, the chemical vapor deposition is, for example, plasma-enhanced chemical vapor deposition (PECVD), and the processing material adopted in the chemical vapor deposition includes silane (SiH₄). Moreover, if the insulating layer 140 is formed by the plasma-enhanced chemical vapor deposition, the silane decomposed into hydrogen.

Each transistor 132 further includes a channel protective layer 132p, and a material of the channel protective layer 132p is a silicon compound, for example, silicon oxide or silicon nitride, wherein the silicon oxide may be silica. In each transistor 132, the channel protective layer 132p partially covers the metal-oxide-semiconductor layer 132c and covers the metal-oxide-semiconductor layer 132c in the channel gap G1. The channel protective layer 132p protrudes from the side edges E1 of the metal-oxide-semiconductor layer 132c. Therefore, each channel protective layer 132p separates the drain 132d from the source 132s of one transistor 132.

In the manufacturing process of the transistor array substrate 100, the channel protective layers 132p serve as masks and isolate the metal-oxide-semiconductor layer 132c in the channel gap G1 from the gas used for the manufacturing process (for example, the hydrogen produced from the decomposition of the silane). Therefore, the channel protective layer 132p prevents the metal-oxide-semiconductor layer 132c in the channel gap G1 from becoming a conductor, so that the transistor 132 keeps the switching function. In this manner, when the transistor 132 is applied in the transistor array substrate 100, the LCD can display images normally.

In addition, the transistor array substrate 100 further includes a gate protective layer 150 as shown in FIG. 1B, and a material of the gate protective layer 150 is, for example, silicon nitride or silicon oxide (for example, silica). The gate protective layer 150 is disposed between the gates 132g and the metal-oxide-semiconductor layers 132c, and is located on the substrate 110. Here, the gate protective layer 150 completely covers the gates 132g.

The transistor array substrate 100 further includes a plurality of first protective pads 160. The first protective pads 160 are disposed between the scan lines 120s and the data lines 120d, and are located at intersections of the scan lines 120s and the data lines 120d respectively. That is to say, in the grid structure formed by the scan line 120s and the data line 120d, the first protective pads 160 are located at intersection points of the grid structure as shown in FIG. 1A.

FIG. 1C is a schematic cross-sectional view taken along line J-J in FIG. 1A. Referring to FIG. 1A and FIG. 1C, each first protective pad 160 has a multilayer structure. In detail, each first protective pad 160 includes a first pad layer 162 and a second pad layer 164. The first pad layers 162 are located between the second pad layers 164 and the scan lines 120s, and the first pad layers 162 may be disposed on the gate protective layer 150, that is, the first protective pad 160 may be located on the gate protective layer 150.

Referring to FIG. 1B and FIG. 1C, in this embodiment, the first pad layers 162 and the metal-oxide-semiconductor layers 132c may be formed of the same film. The method of forming the first pad layers 162 and the metal-oxide-semiconductor layers 132c includes photolithography and etching. Therefore, a material of the first pad layers 162 may be the same as that of the metal-oxide-semiconductor layers 132c, that is, the material of the first pad layers 162 may be IGZO semiconductor or ITZO semiconductor.

Moreover, the second pad layers 164 and the channel protective layers 132p may be formed of the same film. The method of forming the second pad layers 164 and the channel protective layers 132p includes photolithography and etching. Therefore, a material of the second pad layers 164 may be the same as that of the channel protective layer 132p, that is, the material of the second pad layers 164 may be a silicon compound such as silicon oxide (for example, silica) or silicon nitride.

The scan lines 120s enable the gate protective layer 150 to be raised as shown in FIG. 1C. If the data lines 120d are directly formed on the raised gate protective layer 150, the data lines 120d are easily broken at the edge of the scan lines 120s. However, the first protective pads 160 located between the data lines 120d and the scan lines 120s may reduce the risk that the data lines 120d broken at the edge of the scan lines 120s, thereby avoiding breaking the data lines 120d.

Referring to FIG. 1A and FIG. 1B, the transistor array substrate 100 may further include a plurality of common lines 120c and a plurality of second protective pads 170. The common lines 120c and the second protective pads 170 are all disposed on the substrate 110, and the common lines 120c are located below the pixel electrodes 134. The common lines 120c and the scan lines 120s are all arranged side by side and cross the data lines 120d.

The second protective pads 170 are disposed between the common lines 120c and the data lines 120d, and are located at the intersections of the common lines 120c and the data lines 120d respectively. The second protective pads 170 may be further disposed between the common lines 120c and the pixel electrodes 134.

Each second protective pad 170 has a multilayer structure. In detail, each second protective pad 170 includes a third pad layer 172 and a fourth pad layer 174. The third pad layers 172 are located between the fourth pad layers 174 and the common lines 120c, and the third pad layers 172 may be disposed on the gate protective layer 150, so the second protective pad 170 may be located on the gate protective layer 150. Moreover, the fourth pad layers 174 may completely cover the third pad layers 172 and the common lines 120c.

In this embodiment, the third pad layers 172 and the metal-oxide-semiconductor layers 132c may be formed of the same film. The method of forming the third pad layers 172 and the metal-oxide-semiconductor layers 132c may include photolithography and etching. Therefore, a material of the third pad layers 172 may be the same as that of the metal-oxide-semiconductor layers 132c, so the material of the third pad layers 172 may be IGZO semiconductor or ITZO semiconductor.

The fourth pad layers 174 and the channel protective layers 132p may be formed of the same film. The method of forming the fourth pad layers 174 and the channel protective layers 132p may include photolithography and etching. Therefore, a material of the fourth pad layers 174 may be the same as that of the channel protective layers 132p, that is, the material of the fourth pad layers 174 may be a silicon compound such as silicon oxide (for example, silica) or silicon nitride.

The common lines 120c enable the gate protective layer 150 to be raised as shown in FIG. 1B. Therefore, if the data lines 120d are directly formed on the raised gate protective layer 150, the data lines 120d are easily broken at the edge of the common lines 120c. However, the second protective pads 170 located above the common lines 120c may reduce the risk that the data lines 120d are broken at the edge of the common lines 120c, thereby avoiding breaking the data lines 120d.

It is worthy of mentioning that generally an etchant for etching the silicon oxide may damage the silicon nitride. When the material of the gate protective layer 150 is silicon nitride, and the material of the fourth pad layers 174 is silicon oxide (for example, silica), the gate protective layer 150 located at the edge of the common lines 120c has a weak structure and is easy to be damaged by the etchant for etching the silicon oxide.

However, the fourth pad layers 174 completely cover the third pad layers 172 and the common lines 120c, and the method of forming the fourth pad layers 174 includes photolithography, so that in the process of forming the fourth pad layers 174, a photoresist layer (not shown) completely shielding the common lines 120c is certainly formed on the gate protective layer 150. Therefore, the gate protective layer 150 located at the edge of the common lines 120c is protected from being damaged by the etchant, and the fourth pad layers 174 completely cover the common lines 120c.

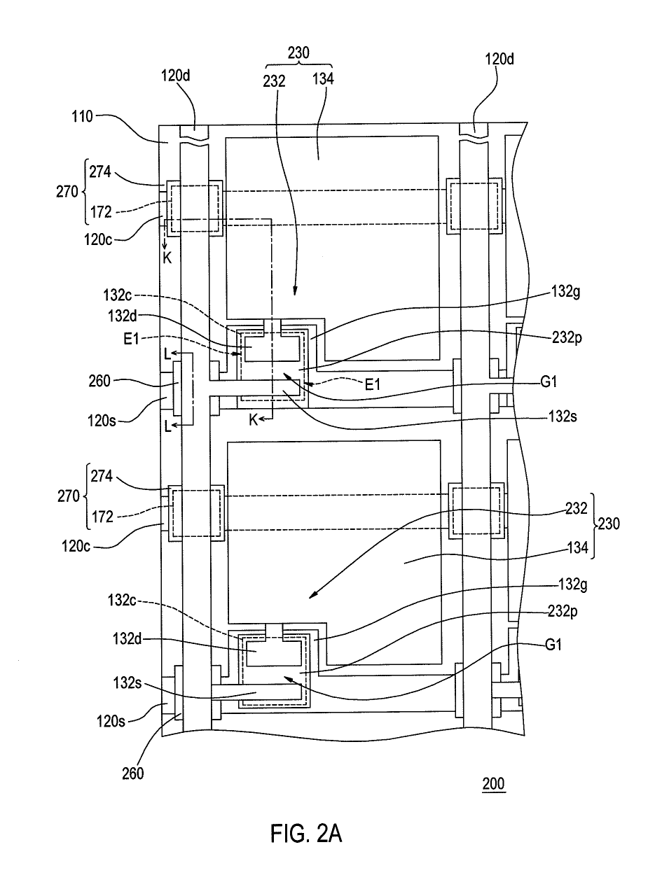

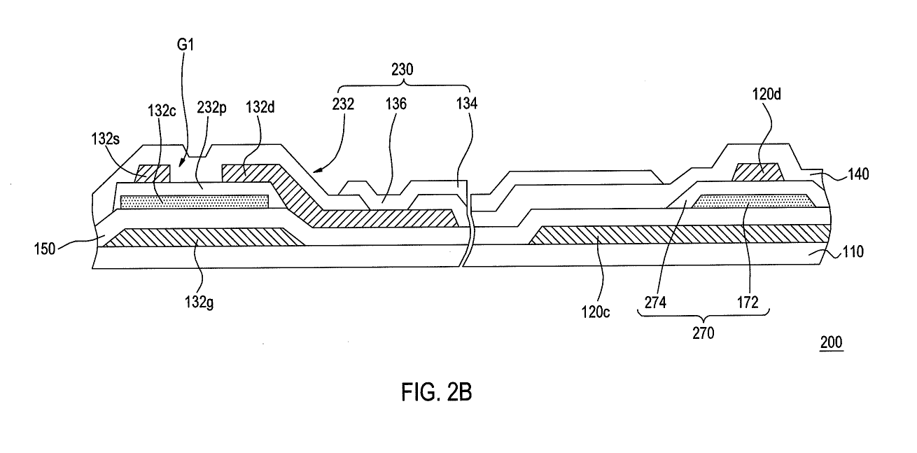

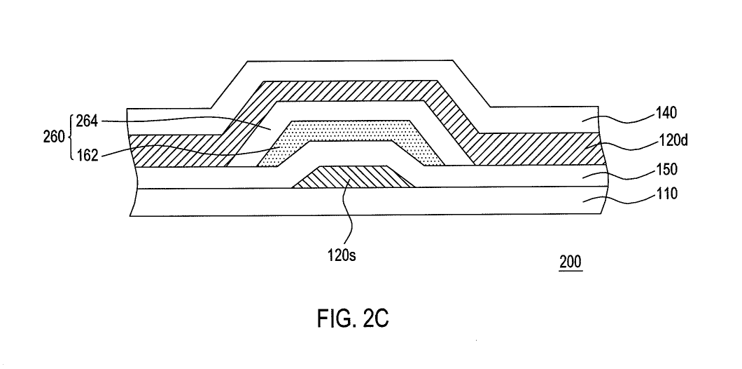

FIG. 2A is a schematic top view of a transistor array substrate according to a second embodiment of the present invention, and FIG. 2B is a schematic cross-sectional view taken along line K-K in FIG. 2A. Referring to FIG. 2A and FIG. 2B, the transistor array substrate 200 of the second embodiment is similar to the transistor array substrate 100. For example, the transistor array substrate 200 may also include a substrate 110, a plurality of scan lines 120s, a plurality of data lines 120d, a plurality of common lines 120c, an insulating layer 140 and a gate protective layer 150. Hereinafter, the difference between the transistor array substrates 100 and 200 is explained in details, and the same technical characteristics will not be described repeatedly.

The major difference between the transistor array substrates 100 and 200 lies in that the transistor array substrate 200 includes a plurality of pixel units 230, a plurality of first protective pad 260 and a plurality of second protective pads 270. Each pixel unit 230 includes a transistor 232, a pixel electrode 134 and a conductive column 136. Each transistor 232 includes a gate 132g, a drain 132d, a source 132s, a metal-oxide-semiconductor layer 132c and a channel protective layer 232p. In each transistor 232, the relative positions of the gate 132g, the drain 132d, the source 132s and the metal-oxide-semiconductor layer 132c are the same as that in the first embodiment, so the details will not be repeated. However, a material of the channel protective layer 232p is different from that of the channel protective layer 232p in the first embodiment. In detail, the material of the channel protective layer 232p is silicon, for example, amorphous silicon.

In each transistor 232, the channel protective layer 232p completely covers the metal-oxide-semiconductor layer 132c, so the channel protective layer 232p not only covers the metal-oxide-semiconductor layer 132c in the channel gap G1, but also protrudes from the side edges E1 of the metal-oxide-semiconductor layer 132c. Moreover, the drain 132d and the source 132s both cover the channel protective layer 232p as shown in FIG. 2B.

Based on the above description, in the manufacturing process of the transistor array substrate 200, the channel protective layer 232p completely covers the metal-oxide-semiconductor layer 132c, so that the channel protective layer 232p may serve as the mask and isolate the metal-oxide-semiconductor layer 132c from the gas used for the manufacturing process (for example, the hydrogen produced from the decomposition of the silane). Therefore, the channel protective layer 232p is able to prevent the metal-oxide-semiconductor layer 132c from becoming a conductor, so that the transistor 232 keeps the switching function, and the LCD using the transistor array substrate 200 can display images normally.

In addition, the first protective pads 260 are disposed between the scan lines 120s and the data lines 120d, and are located at intersections of the scan lines 120s and the data lines 120d respectively. The second protective pads 270 are disposed between the common lines 120c and the data lines 120d, and are located at intersections of the common lines 120c and the data lines 120d respectively.

FIG. 2C is a schematic cross-sectional view taken along line L-L in FIG. 2A. Referring to FIG. 2A to FIG. 2C, each first protective pad 260 includes a first pad layer 162 and a second pad layer 264, and each second protective pad 270 includes a third pad layer 172 and a fourth pad layer 274. The first pad layers 162 are located between the second pad layers 264 and the scan lines 120s, and the third pad layers 172 are located between the fourth pad layers 274 and the common lines 120c. The first pad layers 162 and the third pad layers 172 may be all disposed on the gate protective layer 150.

In this embodiment, the second pad layer 264, the fourth pad layer 274 and the channel protective layer 232p may be formed by the same film, and the method of forming the second pad layer 264, the fourth pad layer 274 and the channel protective layer 232p includes photolithography and etching. Therefore, a material of the second pad layer 264 and the fourth pad layer 274 may be the same as that of the channel protective layer 232p, that is, the material of the second pad layer 264 and the fourth pad layer 274 may be silicon (for example, amorphous silicon).

Generally, the etchant for etching the silicon does not damage the silicon nitride. Therefore, when a material of the gate protective layer 150 is silicon nitride, and a material of the fourth pad layer 274 is silicon (for example, amorphous silicon), the etchant for etching the silicon substantially will not damage the gate protective layer 150. Therefore, it is different from the first embodiment that in the etching process of the fourth pad layer 274, even though the fourth pad layer 274 just above the common lines 120c is not left, the gate protective layer 150 substantially does not be damaged. In other words, in this embodiment, the fourth pad layer 274 is not necessary to cover the common lines 120c completely as shown in FIG. 2A.

To sum up, in the transistor array substrate of the present invention, the channel protective layer included in each transistor covers the metal-oxide-semiconductor layer in the channel gap and protrudes from two side edges of the metal-oxide-semiconductor layer, thereby separating the drain from the source. Therefore, the channel protective layer isolates the metal-oxide-semiconductor layer in the channel gap from the gas used for the manufacturing process (for example, the hydrogen produced from the decomposition of the silane). In this manner, the channel protective layer prevents the metal-oxide-semiconductor from being influenced by the gas used for the manufacturing process. Therefore, the LCD using the transistor array substrate of the present invention is able to display images normally.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A transistor array substrate, comprising:
a substrate;
a plurality of scan lines and a plurality of data lines, all disposed on the substrate and crossing each other;
a plurality of pixel units, each comprising a transistor and a pixel electrode, wherein each of the transistors comprises:
a gate, disposed on the substrate and electrically connected to one of the scan lines;
a drain, electrically connected to one of the pixel electrodes;
a source, electrically connected to one of the data lines, wherein a channel gap exists between the drain and the source;
a metal-oxide-semiconductor layer, disposed between the gate and the drain, and between the gate and the source, and having a pair of side edges, wherein the side edges are located opposite to each other and are located at two ends of the channel gap; and
a channel protective layer, covering the metal-oxide-semiconductor layer in the channel gap and protruding from the side edges of the metal-oxide-semiconductor layer; and
a plurality of first protective pads, disposed between the scan lines and the data lines, and located at a plurality of intersections of the scan lines and the data lines respectively, wherein each of the first protective pads comprises a first pad layer and a second pad layer, and the first pad layers are located between the second pad layers and the scan lines.

2. The transistor array substrate according to claim 1, wherein a material of the metal-oxide-semiconductor layer is IGZO semiconductor or ITZO semiconductor.

3. The transistor array substrate according to claim 1, wherein a material of the first pad layers is the same as a material of the metal-oxide-semiconductor layers.

4. The transistor array substrate according to claim 1, wherein a material of the second pad layers is the same as a material of the channel protective layers.

5. The transistor array substrate according to claim 1, wherein a material of the channel protective layer is silicon compound or silicon.

6. The transistor array substrate according to claim 1, wherein in each of the transistors, the channel protective layer partially covers the metal-oxide-semiconductor layer, and the drain and the source partially covers the metal-oxide-semiconductor layer.

7. The transistor array substrate according to claim 1, further comprising a plurality of common lines and a plurality of second protective pads, wherein the common lines are all disposed on the substrate and are located below the pixel electrodes, the common lines and the scan lines are all arranged side by side and cross the data lines, the second protective pads are disposed between the common lines and the data lines and are located at intersections of the common lines and the data lines respectively.

8. The transistor array substrate according to claim 7, wherein the second protective pads are further disposed between the common lines and the pixel electrodes.

9. The transistor array substrate according to claim 7, wherein each of the second protective pads comprises a third pad layer and a fourth pad layer, and the third pad layers are located between the fourth pad layers and the common lines.

10. The transistor array substrate according to claim 9, wherein a material of the third pad layers is the same as a material of the metal-oxide-semiconductor layers.

11. The transistor array substrate according to claim 9, wherein a material of the fourth pad layers is the same as a material of the channel protective layers.

12. The transistor array substrate according to claim 9, wherein the fourth pad layers completely cover the third pad layers and the common lines.

13. The transistor array substrate according to claim 1, wherein in each of the transistors, the channel protective layer completely covers the metal-oxide-semiconductor layer, and the drain and the source both cover the channel protective layer.

14. The transistor array substrate according to claim 1, further comprising a gate protective layer disposed between the gates and the metal-oxide-semiconductors and completely covering the gates.

15. The transistor array substrate according to claim 1, further comprising an insulating layer, wherein each of the pixel units comprises a conductive column, the insulating layer is located between the transistors and the pixel electrodes, and the conductive columns are disposed in the insulating layer and are connected between the pixel electrodes and the drains respectively.
